(19) United States
(12) Patent Application Publication
(10) Pub. No.: US 2025/0301724 A1
(43) Pub. Date: Sep. 25, 2025

(54) SWITCHING ELEMENT

(71) Applicant: DENSO CORPORATION, Kariya-city (JP)

(72) Inventor: Takuma KATANO, Kariya-city (JP)

(21) Appl. No.: 19/229,613

(22) Filed: Jun. 5, 2025

Related U.S. Application Data
(63) Continuation of application No. PCT/JP2023/034480, filed on Sep. 22, 2023.

(30) Foreign Application Priority Data
Dec. 7, 2022 (JP) 2022-195543

(51) Int. Cl. H10D 62/10; H10D 30/66; H10D 64/23

(52) U.S. Cl. CPC H10D 62/109; H10D 30/668; H10D 64/252

(57) ABSTRACT

A switching element has a gate electrode in a trench of an element part having a central portion and an outer peripheral portion. The element part has an n-type source region. The outer peripheral portion has a p-type body region, an n-type drift region, and p-type electric field relaxation regions disposed at an interval in a lateral direction of the semiconductor substrate, within a depth range including a lower end or below the lower end of the trench. The drift region is located within the interval between the electric field relaxation regions. A value obtained by dividing a width of the electric field relaxation region in the lateral direction by a width of the interval between the electric field relaxation regions is larger in the outer peripheral portion than in the central portion.

### CROSS REFERENCE TO RELATED APPLICATIONS

The present application is a continuation application of International Patent Application No. PCT/JP2023/034480 filed on Sep. 22, 2023, which designated the U.S. and claims the benefit of priority from Japanese Patent Application No. 2022-195543 filed on Dec. 7, 2022. The entire disclosures of all of the above applications are incorporated herein by reference.

### TECHNICAL FIELD

The present disclosure relates to a switching element.

### BACKGROUND

A switching element has a trench-type gate electrode. When the switching element is turned off, the drift region is depleted and an electric field is generated in the drift region. In the switching element, the electric field tends to concentrate at the bottom end of the trench. A p-type electric field relaxation region is provided for suppressing the concentration of electric field at the bottom end of the trench. The electric field relaxation region is disposed in a depth range including the bottom end of the trench, or in a depth range below the bottom end of the trench. The depletion layer is more likely to spread around the bottom end of the trench by providing the electric field relaxation region, such that the concentration of electric field at the bottom end of the trench is relaxed.

### SUMMARY

According to an aspect of the present disclosure, a switching element includes a semiconductor substrate having trenches on an upper surface, a gate insulating film covering an inner surface of the trench, and a gate electrode disposed within the trench and insulated from the semiconductor substrate by the gate insulating film. A part of the semiconductor substrate where the trenches are provided is an element part. The element part has a central portion and an outer peripheral portion. The element part has an n-type source region in contact with the gate insulating film on a side surface of each of the trenches. The element part and the outer peripheral portion have a body region, a drift region, and an electric field relaxation region. The body region is a p-type region in contact with the gate insulating film on the side surface of each of the trenches. The drift region is disposed below the body region, and is separated from the source region by the body region. The drift region is an n-type region in contact with the gate insulating film on the side surface of each of the trenches. The electric field relaxation region is arranged within a depth range including the lower end of the each of the trenches or within a depth range below the lower end of each of the trenches. The electric field relaxation region is connected to the body region, and has plural p-type regions arranged with a gap in a lateral direction of the semiconductor substrate. The drift region is distributed within the gap between the electric field relaxation regions. A value Wp/Wn obtained by dividing a width Wp of each of the electric field relaxation regions in the lateral direction by a width Wn of the gap between the electric field relaxation regions is larger in the outer peripheral portion than in the central portion.

### BRIEF DESCRIPTION OF THE DRAWINGS

FIG. 1 is a plan view of a switching element.

FIG. 2 is a cross-sectional perspective view of a central portion of an element part of the switching element.

FIG. 3 is a cross-sectional view of the central portion extended in x direction, taken along line III-III in FIG. 1.

FIG. 4 is a cross-sectional view of an outer peripheral portion of the element part extended in x direction, taken along line IV-IV in FIG. 1.

FIG. 5 is a cross-sectional view of the central portion extended in y direction, taken along line V-V in FIG. 1.

FIG. 6 is a cross-sectional view of the outer peripheral portion extended in y direction, taken along line VI-VI in FIG. 1.

FIG. 7 is a cross-sectional perspective view of a switching element according to a first modification.

FIG. 8 is a cross-sectional perspective view of a switching element according to a second modification.

FIG. 9 is a cross-sectional perspective view of a switching element according to a third modification.

### DESCRIPTION OF EMBODIMENTS

Even in a switching element provided with an electric field relaxation region, the electric field tends to concentrate at the bottom end of the trench in the outer peripheral portion of the element part where the trench is provided. This specification proposes a switching element for reducing the concentration of electric field in the outer peripheral portion of the element part.

According to an aspect of the present disclosure, a switching element includes a semiconductor substrate having trenches on an upper surface, a gate insulating film covering an inner surface of the trench, and a gate electrode disposed within the trench and insulated from the semiconductor substrate by the gate insulating film. A part of the semiconductor substrate where the trenches are provided is an element part. The element part has a central portion and an outer peripheral portion. The element part has an n-type source region in contact with the gate insulating film on a side surface of each of the trenches. The element part and the outer peripheral portion have a body region, a drift region, and an electric field relaxation region. The body region is a p-type region in contact with the gate insulating film on the side surface of each of the trenches. The drift region is disposed below the body region, and is separated from the source region by the body region. The drift region is an n-type region in contact with the gate insulating film on the side surface of each of the trenches. The electric field relaxation region is arranged in a depth range including the lower end of the each of the trenches or in a depth range below the lower end of each of the trenches. The electric field relaxation region is connected to the body region, and has plural p-type regions arranged with a gap in a lateral direction of the semiconductor substrate. The drift region is distributed within the gap between the electric field relaxation regions. A value Wp/Wn obtained by dividing a width Wp of each of the electric field relaxation regions in the lateral direction by a width Wn of the gap between the electric field relaxation regions is larger in the outer peripheral portion than in the central portion.

In this switching element, the electric field at the bottom end of each trench is relaxed by the electric field relaxation region. Moreover, the electric field relaxation region is arranged so that the value Wp/Wn is larger in the outer peripheral portion than in the central portion. That is, within the depth range of the electric field relaxation region, the ratio of the p-type region is greater in the outer peripheral portion than in the element part. Therefore, in the outer peripheral portion, the depletion layer is more likely to spread from the electric field relaxation region to its surroundings than in the element part. This effectively reduces the concentration of electric field at the bottom end of the trench in the outer peripheral portion. In this manner, this switching element can reduce the concentration of electric field at the outer peripheral portion of the element part.

For example, the switching element may further include: a source electrode covering the upper surface of the semiconductor substrate in the central portion and the outer peripheral portion and in contact with the body region and the source region; and an insulating layer covering an upper surface of the source electrode in the outer peripheral portion.

This configuration can restrict a high electric field from being applied to the gate insulating film in the outer peripheral portion under a high temperature environment.

In the switching element, the outer peripheral portion does not have the source region.

Accordingly, the current flowing to the outer peripheral portion can be suppressed, thereby stabilizing the operation of the switching element.

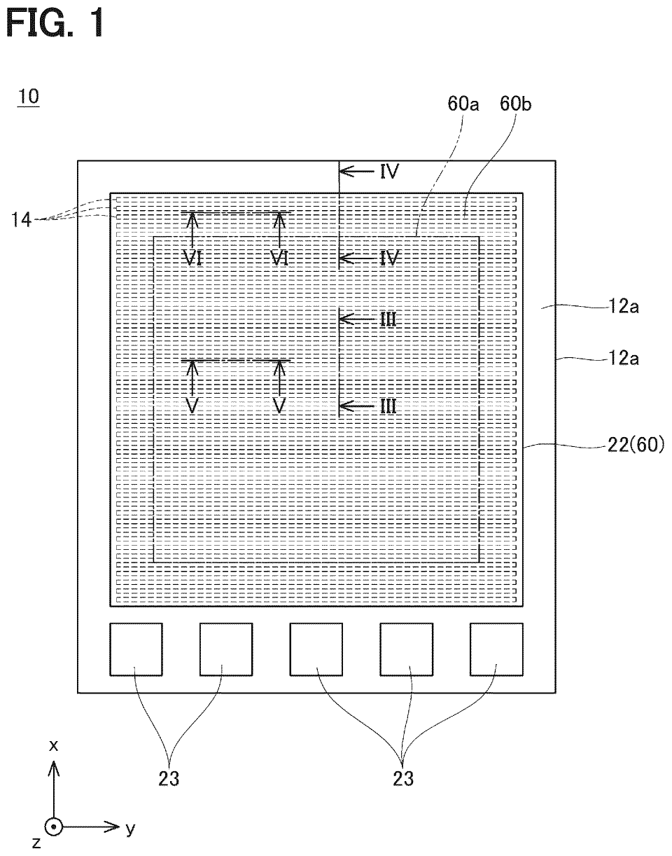

As shown in FIG. 1, a switching element 10 has a semiconductor substrate 12. The semiconductor substrate 12 is made of SiC. The semiconductor substrate 12 may be made of another semiconductor such as silicon (Si) or gallium nitride (GaN). A direction parallel to an upper surface 12a of the semiconductor substrate 12 is referred to as x direction, and a direction parallel to the upper surface 12a and perpendicular to the x direction is referred to as y direction. A thickness direction of the semiconductor substrate 12 is referred to as z direction. A source electrode 22 and plural electrode pads 23 are provided on the upper surface 12a of the semiconductor substrate 12. The electrode pads 23 include an electrode pad for controlling the gate potential, an electrode pad for outputting the potential of the source electrode 22, an electrode pad for outputting the temperature of the semiconductor substrate 12, and the like. Trenches 14 are provided in the upper surface 12a of the semiconductor substrate 12 within an area covered by the source electrode 22. Each trench 14 extends linearly in the y direction. The trenches 14 are arranged at intervals in the x direction. The main portion of the switching element 10 is formed in the area where the trenches 14 are provided. An area of the semiconductor substrate 12 where the trenches 14 are provided will be referred to as an element part 60, when the semiconductor substrate 12 is viewed from the upper side, corresponding to an area overlapping with the source electrode 22. The element part 60 has a central portion 60a and an outer peripheral portion 60b. The outer peripheral portion 60b is provided around the central portion 60a.

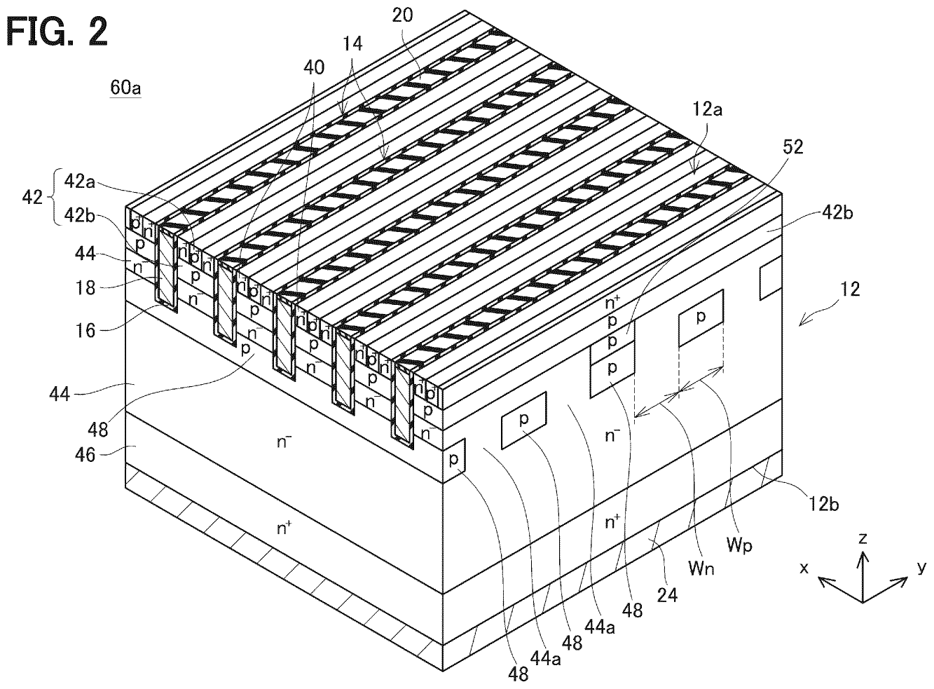

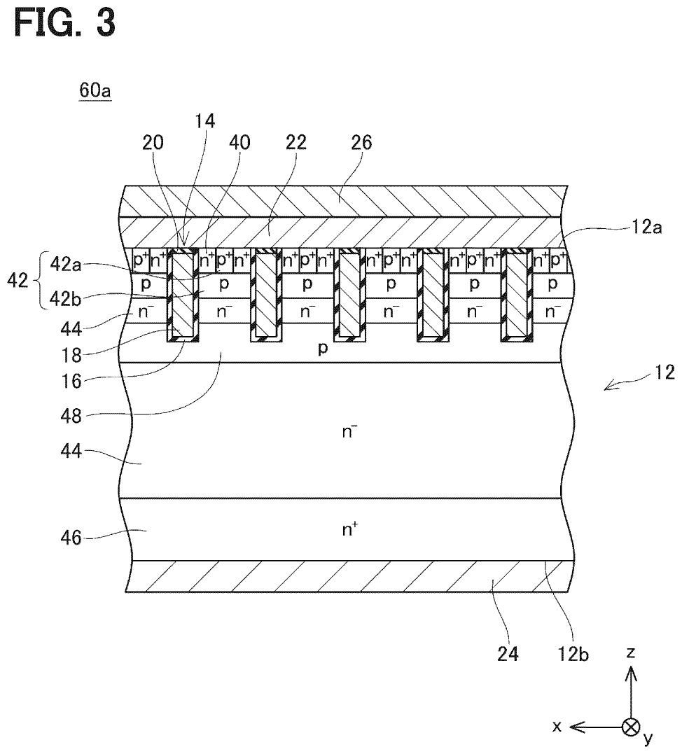

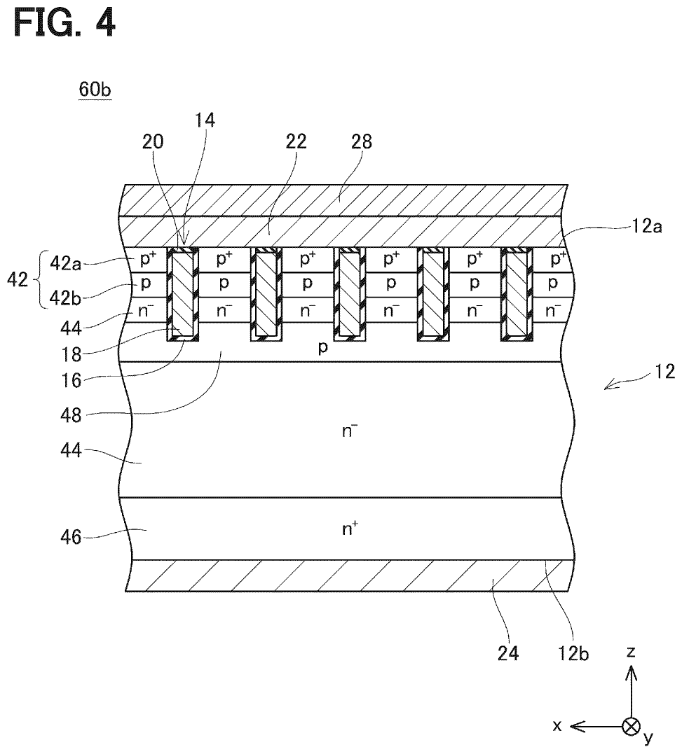

FIGS. 2 to 4 show the structure of the element part 60. More specifically, FIGS. 2 and 3 show the structure of the central portion 60a. FIG. 4 shows the structure of the outer peripheral portion 60b. In FIG. 2, the source electrode 22 is omitted. As shown in FIGS. 2 to 4, the inner surface of each trench 14 is covered with a gate insulating film 16. A gate electrode 18 is disposed in each of the trenches 14. The gate electrode 18 is insulated from the semiconductor substrate 12 by the gate insulating film 16. An upper surface of the gate electrode 18 is covered with an interlayer insulating film 20. The source electrode 22 is insulated from the gate electrode 18 by the interlayer insulating film 20.

The source electrode 22 is made of AlSi. As shown in FIG. 3, in the central portion 60a, the source electrode 22 is covered by the Ni layer 26. Although not shown, the Ni layer 26 is connected to an external electrode block by solder. As shown in FIG. 4, within the outer peripheral portion 60b, the source electrode 22 is covered with an insulating resin layer 28 (for example, a polyimide layer). The insulating resin layer 28 has low thermal conductivity. Therefore, the central portion 60a has a higher heat dissipation property than the outer peripheral portion 60b.

As shown in FIGS. 2 to 4, a drain electrode 24 is provided on the lower part of the semiconductor substrate 12. The drain electrode 24 covers a lower surface 12b of the semiconductor substrate 12.

As shown in FIGS. 2 to 4, the semiconductor substrate 12 has source regions 40, a body region 42, a drift region 44, a drain region 46, and electric field relaxation regions 48.

The source region 40 is an n-type region having a high n-type impurity concentration. As shown in FIGS. 2 and 3, each source region 40 is disposed in an area between the trenches 14. The source region 40 is in ohmic contact with the source electrode 22. The source region 40 is in contact with the gate insulating film 16 at a side surface of the trench 14. The source region 40 is provided in the central portion 60a. As shown in FIG. 4, the source region 40 is not provided within the outer peripheral portion 60b.

As shown in FIGS. 2 to 4, the body region 42 is distributed across the central portion 60a and the outer peripheral portion 60b. The body region 42 has plural contact regions 42a and low concentration regions 42b having a p-type impurity concentration lower than that of the contact region 42a. The contact region 42a is disposed in a range between the trenches 14. Each of the contact regions 42a is in ohmic contact with the source electrode 22. The low concentration region 42b is in contact with the source regions 40 and the contact regions 42a from the lower side. The low concentration region 42b is in contact with the gate insulating film 16 at the side surface of the trench 14. In the central portion 60a, the low concentration region 42b is in contact with the gate insulating film 16 below the source region 40.

As shown in FIGS. 2 to 4, the drift region 44 is distributed across the central portion 60a and the outer peripheral portion 60b. The drift region 44 is an n-type region having a lower n-type impurity concentration than the source region 40. The drift region 44 is distributed to overlap the lower portions of the trenches 14. As shown in FIG. 2, the upper end of the drift region 44 extends into the area between the trenches 14. The drift region 44 is in contact with the low concentration region 42b from the lower side within the range between the trenches 14. The drift region 44 is in contact with the gate insulating film 16 below the low concentration region 42b.

As shown in FIGS. 2 to 4, the drain region 46 is distributed across the central portion 60a and the outer peripheral portion 60b. The drain region 46 is an n-type region having a higher n-type impurity concentration than the drift region 44. The drain region 46 is in contact with the drift region 44 from the lower side. The drain region 46 is in ohmic contact with the drain electrode 24 on the lower surface 12b of the semiconductor substrate 12.

As shown in FIGS. 2 to 4, the electric field relaxation regions 48 are provided in the central portion 60a and the outer peripheral portion 60b. Each of the electric field relaxation regions 48 is disposed in an area surrounded by the drift region 44. The electric field relaxation region 48 is disposed below the low concentration region 42b with a gap therebetween. The drift region 44 is distributed in the space between the electric field relaxation region 48 and the low concentration region 42b. The electric field relaxation region 48 extends linearly in the x direction. The electric field relaxation regions 48 are disposed at intervals in the y direction. The drift region 44 is distributed in the gap between the electric field relaxation regions 48. The drift region 44 in each gap between the electric field relaxation regions 48 will be referred to as a gap 44a. Each of the electric field relaxation regions 48 is disposed in a range including the lower end of the trench 14 in the z direction. Therefore, the electric field relaxation region 48 is in contact with the gate insulating film 16 at the lower end of each trench 14.

As shown in FIG. 2, the semiconductor substrate 12 has a p-type connection region 52. The connection region 52 connects the electric field relaxation region 48 and the low concentration region 42b. Although one connection region 52 is shown in FIG. 2, at least one connection region 52 is provided for each electric field relaxation region 48. Therefore, the potential of each electric field relaxation region 48 is approximately equal to the potential of the body region 42.

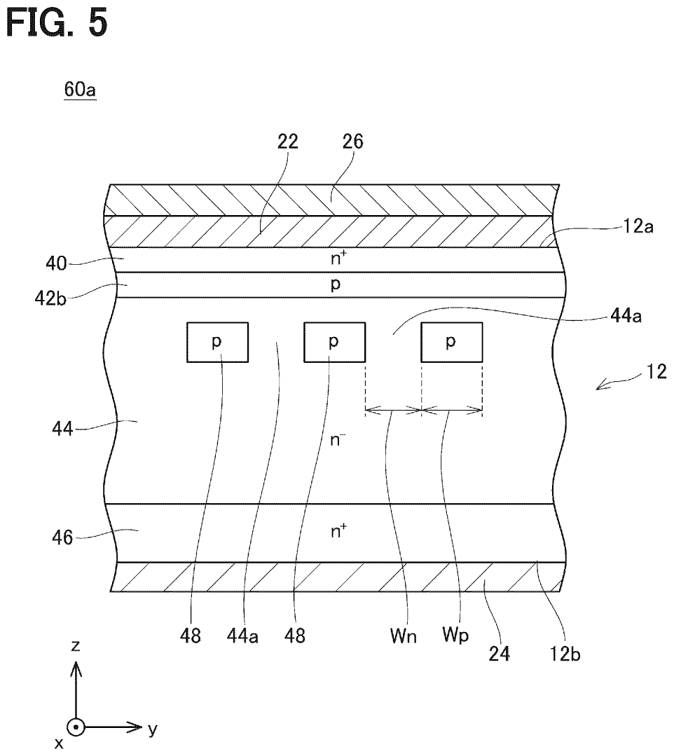

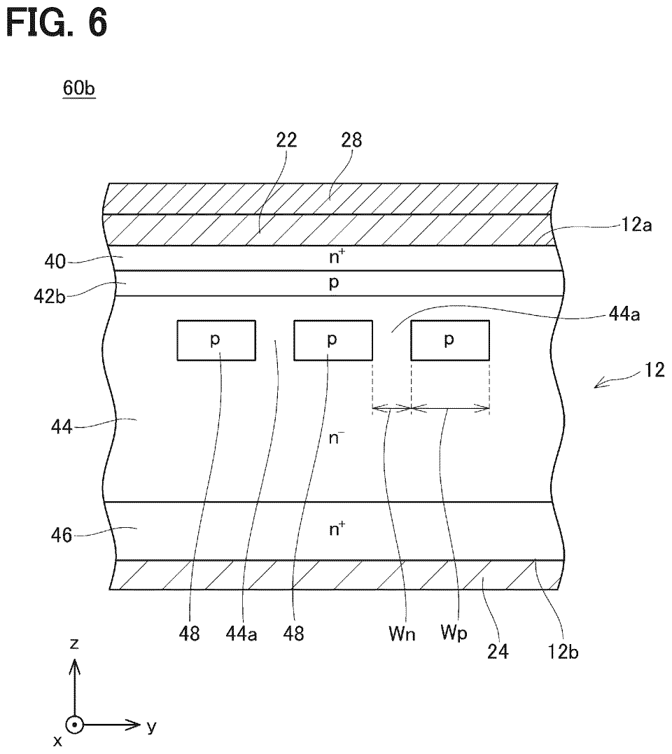

In FIGS. 5 and 6, a symbol Wp indicates the width of each electric field relaxation region 48 in the y direction, and a symbol Wn indicates the width of each gap between the electric field relaxation regions 48 in the y direction (that is, the width of the gap 44a). As shown in FIGS. 5 and 6, the width Wp of the electric field relaxation region 48 is narrower in the central portion 60a than in the outer peripheral portion 60b. Furthermore, the width Wn of the gap 44a is larger in the central portion 60a than in the outer peripheral portion 60b. Therefore, the value Wp/Wn obtained by dividing the width Wp by the width Wn is smaller in the central portion 60a than in the outer peripheral portion 60b. The value Wp/Wn represents a ratio of the electric field relaxation region 48 to the gap 44a within the range where the electric field relaxation region 48 exists in the z direction.

The operation of the switching element 10 will be described. The switching element 10 is used in a state where a voltage is applied such that the drain electrode 24 has a higher potential than the source electrode 22. When a potential equal to or higher than the gate threshold is applied to the gate electrode 18, a channel is formed in the body region 42 in the vicinity of the gate insulating film 16, and the source region 40 and the drift region 44 are connected by the channel. Therefore, electrons flow from the source electrode 22 through the source region 40 and the channel to the drift region 44. Electrons that have flowed from the channel into the drift region 44 pass through the gap 44a and flow into the drift region 44 below the electric field relaxation region 48. Electrons flow from the drift region 44 through the drain region 46 to the drain electrode 24. In this manner, when a potential equal to or higher than the gate threshold is applied to the gate electrode 18, the switching element 10 is turned on.

As described above, when the switching element 10 is turned on, electrons pass through the gap 44a. In the central portion 60a which is the main portion of the element part 60, the value Wp/Wn is small, so that the ratio of the gap 44a (that is, the n-type region) is large within the depth range in which the electric field relaxation region 48 exists. Therefore, in the central portion 60a, the resistance of the gap 44a is small. Thus, electrons can flow with low loss in the central portion 60a. Within the outer peripheral portion 60b, the value Wp/Wn is large, and the resistance of the gap 44a is large. However, fewer electrons flow in the outer peripheral portion 60b than in the central portion 60a. In this embodiment, since the source region 40 is not provided in the outer peripheral portion 60b, the number of electrons flowing in the gap 44a of the outer peripheral portion 60b is very small. Therefore, even if the resistance of the gap 44a is large in the outer peripheral portion 60b, there is not much loss. Therefore, the on-resistance of the switching element 10 is low.

In the manufacturing process, it is difficult to form the trench 14 with high precision over the entire element part 60, and the shape precision of the trench 14 is likely to decrease in the outer peripheral portion 60b. Therefore, if a high current is passed through the outer peripheral portion 60b, an abnormality is likely to occur in the outer peripheral portion 60b. In the switching element 10 of the embodiment, since the source region 40 is not provided in the outer peripheral portion 60b, almost no current flows in the outer peripheral portion 60b. This allows the switching element 10 to operate stably.

When the potential of the gate electrode 18 is reduced to a potential below the gate threshold, the channel disappears and the switching element 10 turns off. When the switching element 10 is turned off, a reverse voltage is applied to the pn junction at the interface between the body region 42 and the drift region 44. Since the electric field relaxation region 48 has approximately the same potential as the body region 42, a reverse voltage is also applied to the pn junction at the interface between the electric field relaxation region 48 and the drift region 44. Therefore, a depletion layer extends from the body region 42 and the electric field relaxation region 48 to the drift region 44. The depleted drift region 44 holds the voltage between the drain electrode 24 and the source electrode 22. The depletion layer extending from the electric field relaxation region 48 to the drift region 44 depletes the drift region 44 around the bottom end of the trench 14. In this manner, the concentration of electric field in the gate insulating film 16 covering the bottom end of the trench 14 is suppressed, since the drift region 44 is depleted around the bottom end of the trench 14.

Since there is no trench 14 outside the element part 60, the electric field is likely to concentrate at the lower end of the trench 14 within the outer peripheral portion 60b. In contrast, in the switching element 10 of the embodiment, the value Wp/Wn is large in the outer peripheral portion 60b, so that the ratio of the electric field relaxation region 48 (i.e., p-type region) to the gap 44a (i.e., n-type region) is large. Therefore, in the outer peripheral portion 60b, a depletion layer tends to spread from the electric field relaxation region 48 to its surroundings. Therefore, the electric field relaxation region 48 has a greater effect of relaxing the concentration of electric field in the outer peripheral portion 60b than in the central portion 60a. This makes it possible to suppress the concentration of electric field at the bottom end of the trench 14 in the outer peripheral portion 60b. As described above, the outer peripheral portion 60b has lower heat dissipation properties than the central portion 60a, and the outer peripheral portion 60b is more likely to become hotter than the central portion 60a. When a high electric field is applied to the gate insulating film 16 under high temperature, the gate insulating film 16 is likely to deteriorate. By suppressing the concentration of electric field on the gate insulating film 16 in the outer peripheral portion 60b which is prone to high temperatures, deterioration of the gate insulating film 16 can be suppressed more effectively.

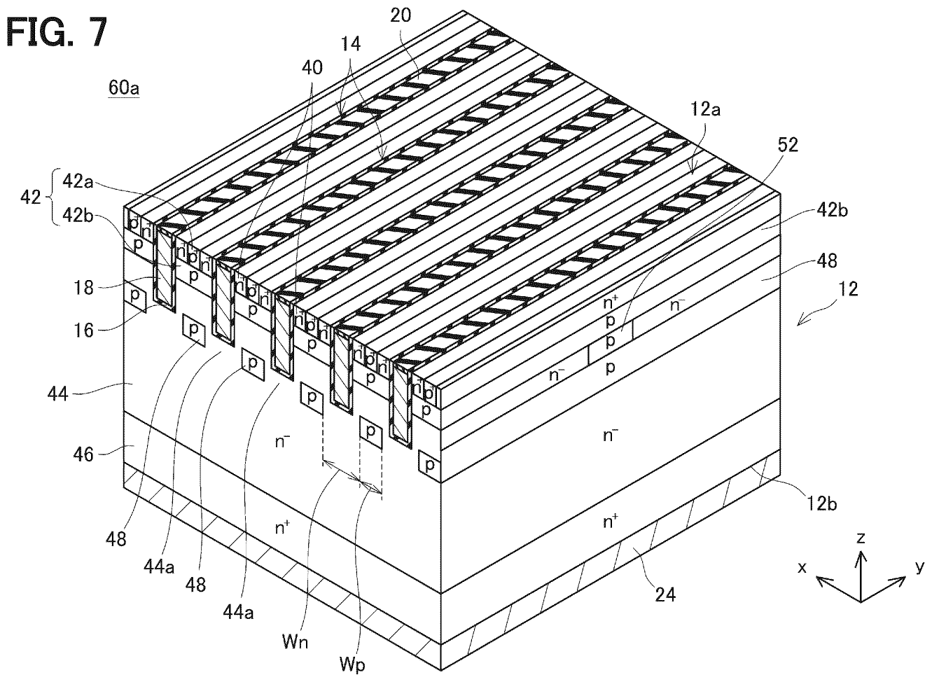

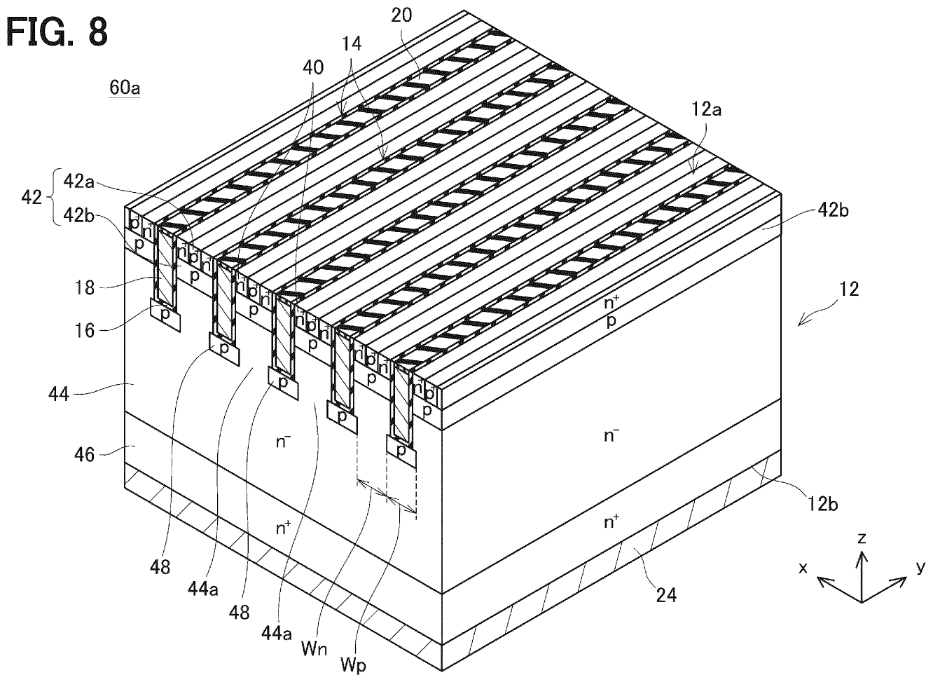

In the embodiment, the electric field relaxation region 48 extends linearly in the x direction intersecting with the trench 14, and the electric field relaxation regions 48 are disposed at intervals in the y direction. However, the electric field relaxation region 48 may extend linearly in the y direction (parallel to the trenches 14) and the electric field relaxation regions 48 may be spaced from each other in the x direction. In this case, as shown in FIG. 7, the electric field relaxation region 48 may be disposed between the trenches 14 in the x direction. Alternatively, as shown in FIG. 8, the electric field relaxation region 48 may be disposed at a position overlapping with the trench 14 in the x direction (i.e., at the bottom of the trench 14). In FIGS. 7 and 8, the concentration of electric field on the gate insulating film 16 in the outer peripheral portion 60b can be suppressed by making the value Wp/Wn larger in the outer peripheral portion 60b than in the central portion 60a.

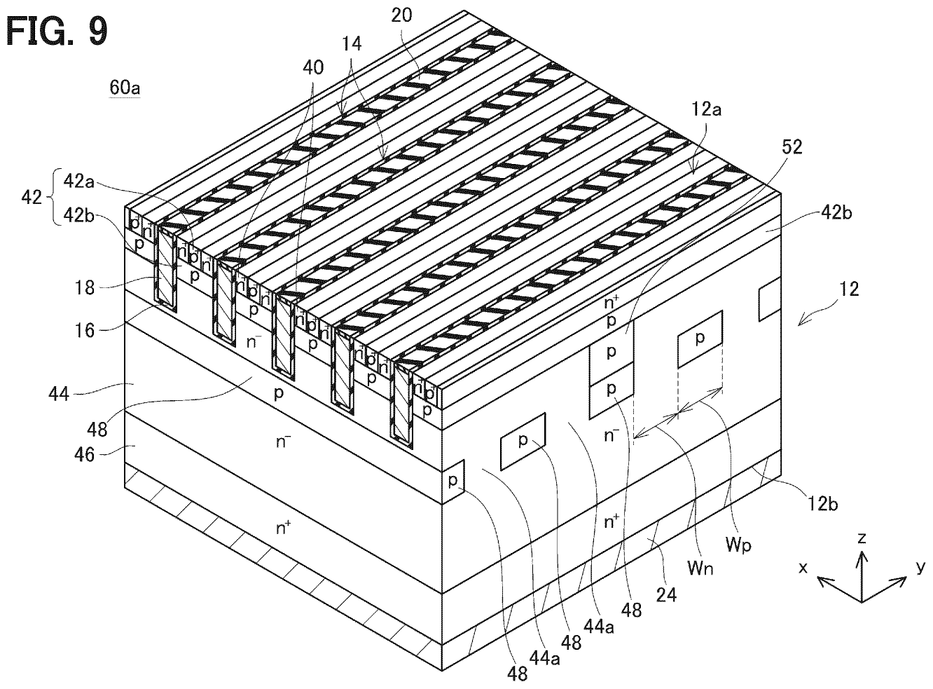

In the embodiment, the electric field relaxation region 48 is positioned in a depth range that includes the lower end of the trench 14, but the electric field relaxation region 48 may be positioned in a depth range that is lower than the lower end of the trench 14. For example, as shown in FIG. 9, when the electric field relaxation region 48 extends linearly in a direction intersecting with the trench 14, the electric field relaxation region 48 may be disposed below the lower end of the trench 14. Even when the electric field relaxation region 48 extends linearly parallel to the trench 14 as in FIGS. 7 and 8, the electric field relaxation region 48 may be disposed below the bottom end of the trench 14. Even if the electric field relaxation region 48 is disposed below the lower end of the trench 14, the concentration of electric field at the lower end of the trench 14 can be suppressed.

In the embodiment, the source region 40 is not provided in the outer peripheral portion 60b, but the source region 40 may be provided in the outer peripheral portion 60b.

In the embodiment, the width Wp is wider in the outer peripheral portion 60b than in the central portion 60a, and the width Wn is narrower in the outer peripheral portion 60b than in the central portion 60a. However, if the value Wp/Wn is greater in the outer peripheral portion 60b than in the central portion 60a, the widths Wp and Wn in the central portion 60a and the outer peripheral portion 60b may be set in any manner. For example, the width Wp may be greater in the outer peripheral portion 60b than in the central portion 60a, and the width Wn may be the same between the outer peripheral portion 60b and the central portion 60a. For example, the width Wp may be the same between the outer peripheral portion 60b and the central portion 60a, and the width Wn may be narrower in the outer peripheral portion 60b than in the central portion 60a.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A switching element comprising:
a semiconductor substrate having an upper surface in which a plurality of trenches is formed;
a gate insulating film covering an inner surface of the trench; and
a gate electrode disposed inside the trench and insulated from the semiconductor substrate by the gate insulating film, wherein
a part of the semiconductor substrate in which the plurality of trenches is provided is defined as an element part,
the element part has a central portion and an outer peripheral portion,
the element part has an n-type source region in contact with the gate insulating film at a side surface of each of the trenches,
the central portion has the source region,
the peripheral portion has no source region,
the element part and the outer peripheral portion have:
a p-type body region in contact with the gate insulating film at the side surface of each of the trenches;
an n-type drift region in contact with the gate insulating film at the side surface of each of the trenches, disposed below the body region and separated from the source region by the body region; and
a plurality of p-type electric field relaxation regions arranged with a gap therebetween in a lateral direction of the semiconductor substrate,
the plurality of p-type electric field relaxation regions is disposed within a depth range including a lower end of each of the trenches or within a depth range below the lower end of each of the trenches, and connected to the body region,
the drift region is distributed within the gap between the electric field relaxation regions, and
a value obtained by dividing a width of each of the electric field relaxation regions in the lateral direction by a width of the gap between the electric field relaxation regions is larger in the outer peripheral portion than in the central portion.

2. The switching element according to claim 1 further comprising:
a source electrode covering the upper surface of the semiconductor substrate at the central portion and the outer peripheral portion; and
an insulating layer covering an upper surface of the source electrode at the outer peripheral portion, wherein
the source electrode is in contact with the body region and the source region at the central portion, and
the source electrode is in contact with the body region at the outer peripheral portion.
